(19) United States
(12) Patent Application Publication
(10) Pub. No.: US 2011/0241720 A1
(43) Pub. Date: Oct. 6, 2011

(54) DC TEST POINT FOR LOCATING DEFECTIVE PV MODULES IN A PV SYSTEM

(75) Inventor: BERNHARD BECK, Volkach OT Dimbach (DE)

(73) Assignee: Adensis GmbH, Dresden (DE)

(21) Appl. No.: 12/899,136

(22) Filed: Oct. 6, 2010

(30) Foreign Application Priority Data
Oct. 8, 2009 (DE) 10 2009 048 691.7

(51) Int. Cl. G01R 31/26

(52) U.S. Cl. 324/761.01

(57) ABSTRACT

A method and an apparatus for carrying out the method are proposed for identifying defective photovoltaic modules. Two clamp-on ammeters are provided which are connected to a test data acquisition unit for simultaneous measurement of two DC currents. The position of the clamp-on ammeters at the time of the measurement is determined with a position registration means, and measured data and position data are transmitted via an antenna to a data processing center or recorded in a data memory element for further processing.

### CROSS-REFERENCES TO RELATED APPLICATIONS

This application claims the priority of German Patent Application, Serial No. 10 2009 048 691.7, filed Oct. 8, 2009, pursuant to 35 U.S.C. 119(a)-(d), the content of which is incorporated herein by reference in its entirety as if fully set forth herein.

### BACKGROUND OF THE INVENTION

The present invention relates to a method for locating a defect PV module within a larger PV facility and to a corresponding apparatus.

The following discussion of related art is provided to assist the reader in understanding the advantages of the invention, and is not to be construed as an admission that this related art is prior art to this invention.

Large PV facilities may include thousands of PV modules which must be measured individually to identify and locate a damaged module. This complex procedure is required because the existence of one or more defective modules is barely noticeable for the total power. A defective module where one photovoltaic cell is non-conducting or where a solder connection between two cells is severed causes the entire strand to fail, for example 10 PV modules connected in series, because a single interruption also interrupts the series connection. At a power of 2 MW, the contribution on a strand corresponds, for example, to about 2 kW or 1/1000 of the power. Even several strands which become defective over time are not immediately noticeable, because the deviation of the generated power may also depend on the weather. Permanently installed systems for measuring the power are associated with significant costs that can not be justified.

In addition to the aforementioned problem of the unidentified reduction in power of the PV system, it is particularly important during the warranty period that justified complaints are identified in order to seek remedy from the manufacturer of the defective PV module.

Different approaches for testing the performance of PV modules are known in the art. In all methods delivering a reliable result, the PV system must be disconnected from the inverter and connected to a test device.

The test device may be a multimeter which determines the short-circuit current and the open-circuit voltage of a PV module, a strand or a PV unit. This measurement is intended to identify the basic function of PV module, strand or PV unit.

For determining the performance of a PV module, a strand or a PV unit, the PV module, strand or PV unit is preferably connected to a U-I curve tracer configured to measure the corresponding U-I curve. The measured curve is supplemented by the measured value from an irradiation sensor or a reference solar cell as well as by the measured value from a temperature sensor which measures the temperature of the PV module. The STC performance value (standardized performance value for photovoltaic modules) is computed from the aforementioned values—irradiation, temperature, voltage and current. However, this value has a high uncertainty due to the large number of tolerances of the sensors considered in the calculation.

Performing measurements with a clamp-on ammeter is also known in the art, because the current of a PV module, a strand or a PV unit can then be determined during operation. Because the voltage, irradiation and temperature are not known, this type of measurement is only suitable for testing the underlying functionality and for checking of fuses. All conventional methods and apparatuses do not provide adequate precise information regarding accuracy, test duration and applicability during ongoing operation.

It would therefore be desirable and advantageous to provide an improved method to obviate prior art shortcomings and to identify with little technical complexity and within a short time a defective strand in which a defective PV module is located.

### SUMMARY OF THE INVENTION

According to one aspect of the invention, a method for simultaneously measuring the currents of two PV units using two clamp-on ammeters and a test data measuring unit, which provides the measured values to an evaluation unit for determining the performance of the corresponding PV units. The following situations can be distinguished: a) with identically constructed PV units operating at the same operating voltage, the PV unit having a smaller current is identified as the PV unit having less power, b) with identically constructed PV units operating at the different operating voltages, the PV unit having a smaller product of measured current and measured operating voltage of the PV unit associated with the respective current value is identified as the PV unit having less power, c) with differently constructed PV units operating at the same operating voltage, the PV unit having a smaller current is identified as the PV unit having less power, and d) with differently constructed PV units operating at different operating voltages, the PV unit having a smaller product of measured current and measured operating voltage of the PV unit associated with the respective current value is identified as the PV unit having less power.

With the presently used terminology, a PV unit can refer to a single module, a single strand, but also a PV field constructed from several parallel strands. With the presently discussed large facilities of 100 MW and more, complete PV facilities can also be regarded as a PV unit in the context of the invention, if several of these PV facilities form a spatially contiguous overall system.

In a practical approach, the currents from two PV fields are compared with each other. It is hereby unimportant which of the two existing connecting cables are used for the measurement. However, it is important that the measurement is performed simultaneously, so that the same conditions are present at the time of the measurement. These are substantially the temperature of the PV cells and the voltage between the connecting cables. If everything is satisfactory, then two identically constructed PV fields operating at the same voltage would also have to generate the same DC current, unless one of the strands of one of the fields is defective. If one of the measured currents is substantially lower, for example lower by more than 5%, than the simultaneously measured other current, then in the next step the measurement is refined by measuring the currents of two strands of the potentially defective PV field in the same manner as before and comparing these currents with each other. If the deviation of both currents is in the tolerance range of, for example, the aforementioned 5%, then the strands are satisfactory and the measurement is repeated on two other strands of the same field. In this way, one strand after the other is compared with one another, until the strand which is disconnected or carries an unacceptable current is identified. The defective module in the strand can then be readily identified.

With differently constructed PV units, the currents through each of a corresponding connecting cable of both PV units are simultaneously measured (also referred to as determined). Thereafter, the ratio between the two currents is formed in a suitable component. Finally, it is determined by comparing the ratio with a comparison ratio formed from measured values of the DC current which were flowing through the respective connecting cable of the two PV units at an earlier time than the time of the present measurement, if a change in the performance in one of the PV units has occurred.

In a facility with differently constructed PV units, there is a difficulty that the PV fields have, for example, ten or only eight strands, or the strands have a different number of PV modules. In theory, the first method could also be used by setting up a table with correction factors which takes this difference into consideration and by weighting the individual current measurements during the comparative simultaneous current measurements accordingly.

The aforementioned advantageous embodiment can be simplified by simultaneously measuring the currents of two PV fields without the knowledge of the differences and by computing the ratio between the currents. This can advantageously be done at about the same time the PV facility is set up, if one assumes that the supplied and tested PV modules operate satisfactory when the PV facility is started up. A performance ratio of the two PV units is then established, where other parameters, such as the actual solar irradiation, the actual temperature, etc., are not considered, because these are identical for both PV units. At a later time, for example several months before the warranty period expires or when the power of the facility is insufficient, the current measurement on the PV units is repeated. If the ratio is still the same, it can be concluded with high probability that the PV units operate correctly, because a malfunction having an identical effect on the two PV units is rather unlikely. However, if the ratio is different, then depending on the direction of the change, one or the other of the compared PV units must be defective.

In this context, the following steps can advantageously be performed in a PV facility with at least three PV units: i) in all existing PV units a current measurement is performed simultaneously on each of two PV units forming a pair, until the current of each PV unit has been measured at least once; ii) a ratio is computed from the two current values measured for each pair; and iii) the ratios are stored in an electronic memory element. With this approach, the pair formation for the current measurement after step i) is advantageously performed on adjacent PV units, wherein the pairs of adjacent PV units are selected so that at least partially a continuous chain of linked pairs is formed. The advantage (even without pair formation) will become clearer from the following example:

The comparison measurement is started in a PV facility with n=100 fields, each having 10 strands, each strand having eight PV modules belonging to the fields 1 and 2, which are then to be considered as a PV unit within the meaning of the claims, resulting in a ratio of 1:1=1, i.e., identical current values. In the next measurement, the fields 2 and 3 are compared with each other, resulting in a ratio of 1.1:1=1.1. In the following measurements for the PV fields 3 and 4, a ratio of 0.98:1=0.98 is obtained. 99 of these sequential measurements are performed, up to the last measurement between the PV units or fields n-1 and n. The relationship between all fields can then be computed, which is, for example from the first field to the last field, the multiplication of all 99 ratios or factors. Between the first field and the fourth field, the relationship is 1 times 1.1 times 0.98=1.078. If the absolute current is measured on one of the PV units at a later time, then the total current or the total power of the photovoltaic facility that would be present without a malfunction, the degradation or defect can be computed in a computing unit from the absolute current value and the ratios of the stored measured values. If the theoretically determined total value of the PV facility is significantly greater than the instantaneous supplied value at the time of the individual measurement on one of the PV units, then conclusions can be drawn about a fault. When several inverters are supplied, the PV units should be set to the same voltage value during the simultaneous measurement, which would then also be set during the later current measurement for determining the total power of the PV facility.

Advantageously, the aforementioned pairs form links. The term “current pair” always refers to the value pair of the two simultaneously measured currents. The advantage is here the simplified association of the test location with the measured current values. In principle, any field of the facility can be combined with any other field to from a pair. The same association must then also be maintained for the later measurement, because the computed ratios are valid only for this one pair. This identical association is more difficult with randomly selected pairs than with pairs of adjacent PV units. This association is also important for the installer who must travel with the test device to the fields to be measured. If these are far apart, then extension cables must be used which may be several hundred meters long and may therefore falsify the result. Conversely, a measurement of adjacent PC fields can be performed with a cable to the test means, typically clamp-on ammeters, several meters long. Forming the ratios among adjacent pairs is also advantageous because the PV cell temperature of adjacent PV units is at least similar. A cloud will not follow to a sharp geometric dividing line of the PV units on the ground, thereby causing a longer cooldown time, but will shadow adjacent fields rather uniformly.

In this context, a cross check would also be useful, wherein after a predetermined number of, for example ten, current value pairs measured in a certain sequential order, a cross measurement is performed, wherein simultaneously the current values of the previously measured first PV unit and of the last measured PV unit are determined, the ratio is formed and compared with the product of the ten individual ratios. For example, if a sequence of ten ratios was computed based on ten individual measurements on the ten PV unit pairs, resulting in a total of 1:1.1 (corresponding to the product of the ten individual ratios), then the cross ratio of the current of the first PV unit to the current of the last measured PV unit would also be 1:1.1 with a correct calibration of the clamp-on ammeters. If this is not the case, for example, if the ratio is 1:1.15, then it can be concluded that the calibration is not optimal and the ten computed individual ratios can be corrected by distributing the difference, e.g., 0.05, uniformly across all ten ratios. This corresponds to an increase by 0.005 for each of the ratios computed for the ten PV unit pairs.

It is also easier for personnel performing the measurements if at each measurement after step i) an identification of the test location, in particular the location of the measurement, is registered and stored together with the value of the current pair measured at the location or the ratio computed therefrom. The location of the measurement can be recorded at the time of the current measurement with GPS, with an RFID chip or with a barcode reader. The chip or the RFID label is permanently attached at a location of the support structure for the PV system. If the PV units are adjacent to each other when the pairs are formed, then the installer needs to walk only from one test location to the next test location, place the clamp-on ammeters around each supply cable, start the measurement process and move after the measurement to the next test location. This process can be recorded at the first measurement, i.e., when the ratio is formed, so that the installer moves for the repeat measurement or test only to the beginning of the chain where he starts the test. When the measurement or the formation of the ratio is completed, this is signaled to the installer with an LED on the test device, whereafter he moves to the next test location. The measurement is released only when signaled to the installer by an additional LED of different color. The signal is provided if either the correct GPS signal with “target reached” is transmitted, the transponder reaction with the RFID label is positive, the correct, previously stored barcode is read, and the like. The installer becomes only then aware that he has arrived at the intended next test location, with the measured values being the intended values.

With less qualified personnel, any sequential order during the acquisition of the measured values may be eliminated, relying only on the correct correlation between test location and measured value. The computing unit can then determine that all measured values, i.e., for each pair at least one measured value, have been determined and can then sort the measured values in a predetermined order. The process of changing from one adjacent to the next adjacent PV units is particularly advantageous if a position indication is missing.

The ratios between the two simultaneously measured DC current values can be formed directly on site, or the measured values of each pair can be transmitted together with the identification to a data processing site, where they are stored and processed.

For attaining a high reliability of the stored ratios, it is advantageous to consecutively measure the current briefly (e.g., for several milliseconds) several times, for example five to ten times, and to form the arithmetic mean over the consecutively measured current. The ratio is then formed from the arithmetic means of the current values and has therefore a more reliable foundation. The voltage value measured, for example, at the inverter between the two connecting cables of the PV unit can also be stored together with the measured values of the DC current or the ratios.

Because each measurement also contributes to the measurement error due to the subsequent multiplication of the ratios, the test device is advantageously calibrated after each third to twentieth measurement, preferably after each fifth to tenth measurement to ensure an acceptable measurement tolerance.

The described method is not intended for daily use, but rather for testing the performance of the PV facility in regular intervals of, for example, several months. All PV units connected to the same inverter may advantageously be held at a constant voltage during all DC current measurements by setting the MPP (Maximal Power Point) controller of the inverter to this constant voltage value.

For assessing how far an individual PV unit deviates from its expected power output, a single of the PV units is advantageously defined by a current measurement, a voltage embodiment, an irradiation intensity and a direct or indirect temperature measurement on the semiconductor as reference PV unit according to the standardized test conditions (STC) defined for photovoltaic modules for determining the standard power, in order to thereafter compute the standard power (according to STC) of a PV unit linked by way of the current value pairs.

In particular, with identically constructed TV units, the individual performance of the PV unit can also be estimated through comparison with the reference PV unit which was previously defined as such. This is advantageously the PV unit which produced the highest power output when the power output was first determined on a day with ideal weather, for example when the photovoltaic facility was started up. This power output is then used as the best available reference for the installed type of the PV unit. If the power output of any other PV unit is reduced compared to a limit value of, for example, 95% of the power output of the reference unit, then a faulty installation or a defective component may be inferred.

With respect to the apparatus, the aforementioned object is attained with a current measuring device having two clamp-on ammeters for simultaneous measurement of a DC current, with a position registration means for measuring the position of the clamp-on ammeters at the time of the measurement and with an antenna for transmitting the measured data and the position data and/or with a data memory element for writing the measured data and the position data. The clamp-on ammeters are each placed around one of the two corresponding connecting or supply cables associated with a PV unit. Because such clamp-on ammeters for DC measurements operate with magnetic fields, a regular calibration is required, which is done using an integrated DC source supplying a measurement shunt resistor. The clamp-on ammeters are placed around an electrical conductor, preferably a hoop, through which a calibration current generated by the DC voltage source flows. The conductor is constructed to simultaneously receive both clamp-on ammeters, so that the calibration process for both clamp-on ammeters is identical.

According to another aspect of the invention, a current measuring device has two clamp-on ammeters for simultaneous measurement of a DC current, with a position registration means for measuring the position of the clamp-on ammeters at the time of the measurement and with an antenna for transmitting the measured data and the position data and/or with a data memory element for writing the measured data and the position data. The clamp-on ammeters are each placed around one of the two corresponding connecting or supply cables associated with a PV unit. Because such clamp-on ammeters for DC measurements operate with magnetic fields, a regular calibration is required, which is done using an integrated DC source supplying a measurement shunt resistor. The clamp-on ammeters are placed around an electrical conductor, preferably a hoop, through which a calibration current generated by the DC voltage source flows. The conductor is constructed to simultaneously receive both clamp-on ammeters, so that the calibration process for both clamp-on ammeters is identical.

For a more continuous testing of the performance of the PV facility, a stationary current test device is provided as an alternative, which measures the absolute current of one of the PV units and transmits a result for processing to a computing unit which computes from the ratios and the stationarily determined current value, as well as from the voltage at the inverter(s) the theoretical total power output of the facility. This power output is then compared with the actual power level at the time of the measurement, allowing conclusions about a continuous degradation or a fault.

According to another embodiment for solving a further aspect of the object with respect to the device, a stationary current and voltage measuring unit is provided which measures the current of a single PV unit and transmits a result to a computing unit for processing, which computes the theoretical total power output of the facility from the ratios of the current value pairs and the stationarily determined current value, as well as from the voltage values determined for the current value pairs and the stationarily determined voltage value.

### BRIEF DESCRIPTION OF THE DRAWING

Other features and advantages of the present invention will be more readily apparent upon reading the following description of currently preferred exemplified embodiments of the invention with reference to the accompanying drawing, in which:

FIG. 1 illustrates the basic structure of a large-scale photovoltaic system,

FIG. 1a shows a detail of FIG. 1,

FIG. 2 shows a test and evaluation unit for use in a facility according to FIG. 1, and

FIG. 3 shows a housing, which houses the measuring and evaluation unit, with a hoop and a calibration conductor.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments are sometimes illustrated by graphic symbols, phantom lines, diagrammatic representations and fragmentary views. In certain instances, details which are not necessary for an understanding of the present invention or which render other details difficult to perceive may have been omitted.

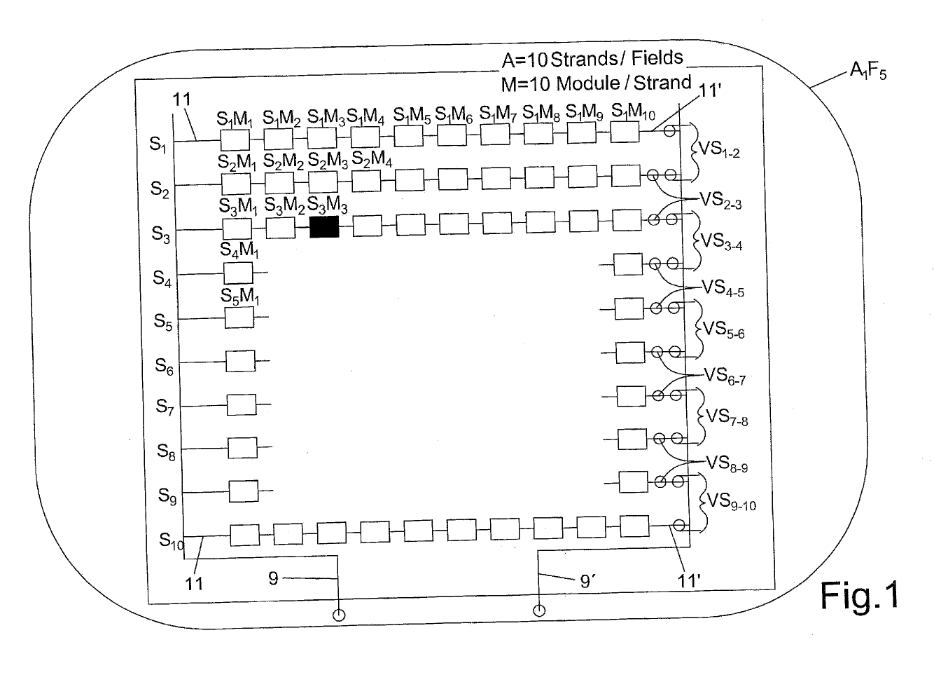

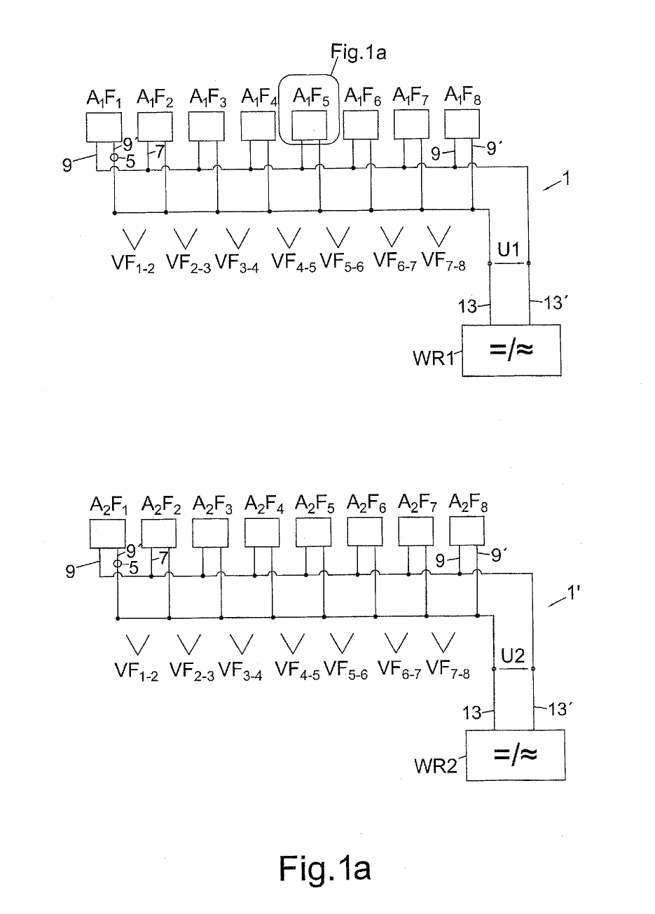

Turning now to the drawing, and in particular to FIG. 1, a first and a second identically constructed photovoltaic facility are indicated with A₁ and A₂, respectively. In other words, each PV facility 1, 1′ has eight fields F₁ to F₈ and F_{1′} to F_{8′}, respectively, with an additional prefix A₁ designating the facility 1 and A₂ designating the facility 2. Only the first facility A₁ will be described in detail.

As discussed above, the first facility A₁ has eight fields A₁F₁, A₁F₂, . . . to A₁F₈, all of identical construction. As shown, for the example, in the detailed FIG. 1a for the field A₁F₅ (facility 1, fifth field), each facility field AF has ten strands S electrically connected in parallel and continuously numbered S₁ to S₁₀. Each strand S₁ to S₁₀ has ten PV modules M connected in series and continuously numbered M₁ to M₁₀. A single PV module from the 100 PV modules S₁M₁ to S₁₀M₁₀ is shown fully in black, namely the photovoltaic module S₃M₃, which is assumed to be defective. Each module M is composed of about 60 PV cells connected in series. The PV cell is the smallest unit capable of converting solar radiation into electrical current. The 60 cells are connected in series, producing a voltage of 60 V across the module. With ten modules connected in series, the voltage across the entire strand, also referred to as strand voltage, is 600 V. If a single cell of the 10×60=600 cells of a strand is non-conducting, or one of the connections between the cells is severed, then the entire strand fails to supply current due to the series connection. Such an exemplary situation is assumed with the module M₃S₃. It will be described later how the strand S and then also the module M can be identified.

The underlying problem is important because depending on the size of the PV facility, as mentioned above, it is not noticeable when a single strand malfunctions, because its contribution to the total power output is relatively small. Other hand, like with a dripping faucet, which only loses small amounts of water, these small amounts add up over time, in PV facilities over several decades to a substantial loss. It is therefore necessary for economic, but also warranty-related reasons to evaluate the performance not only of the entire facility, but also of individual PV units of the facility.

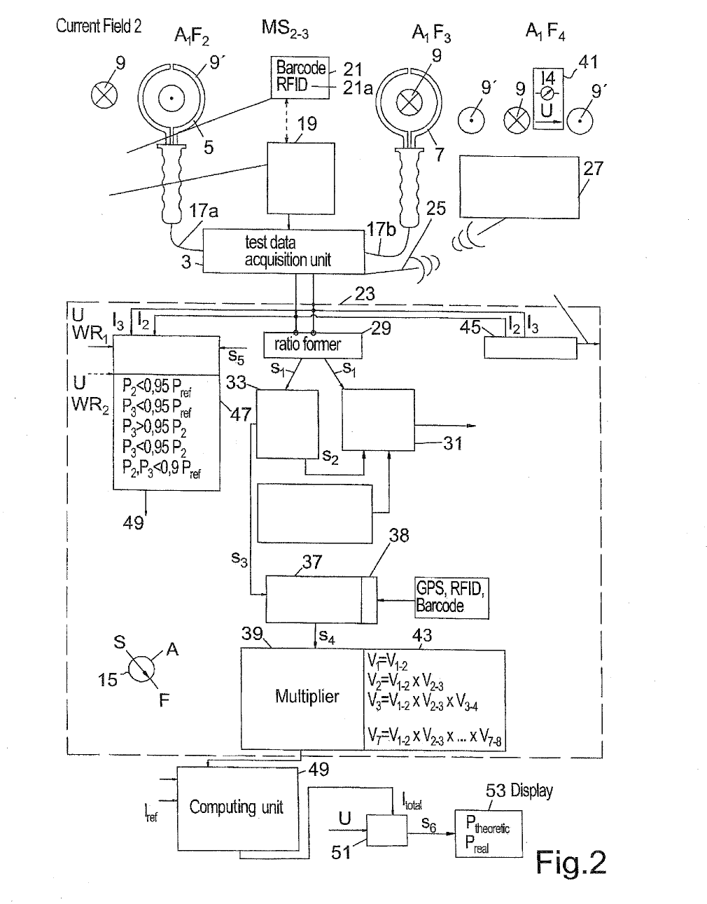

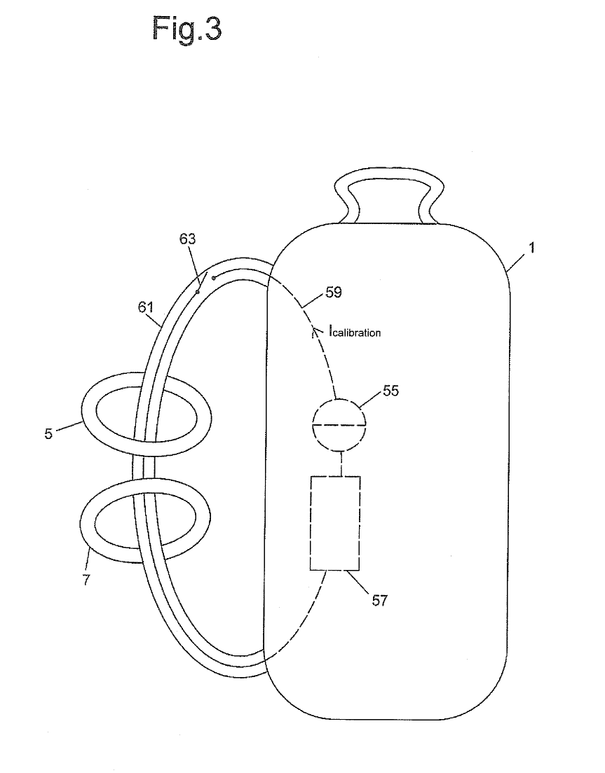

For this purpose, the measuring and evaluation device 3 described in detail with reference to FIGS. 2 to 3 is employed as follows. The device has two clamp-on ammeters 5 and 7, which are configured to be applied around one of the electrical supply cables 9, 9′ of the fields F, one of the two supply cables 11, 11′ to the strands S, or one of the two supply cables 13, 13′ to an inverter WR. Such clamp-on ammeters for measuring DC currents are known in the art. The clamp-on ammeters 5, 7 are connected to an evaluation unit 15 which will be described below.

First, the approach for identifying the defective strand S₃ will be described. For sake of clarity, it will be assumed that all PV modules M are otherwise identical and operate perfectly. First, the clamp-on ammeters 5 is placed around one of the supply cables 13, 13′ to the first inverter WR₁, and the second clamp-on ammeters 7 is the placed around one of the supply cables 13, 13′ to the second inverter WR₂. Because the facility A₁ has in the defective module, it will generate less current and hence less power than the PV facility A₂. During the measurement process itself, the operating voltages U₁ and U₂ of the two inverters WR₁ and WR₂ must be set to the same voltage to make a comparison of the currents meaningful. This is done by intervening on the MPP controller, as is customary in the technical field of solar technology. In this first step, it is determined that the fault causing the reduced power must be located in the facility part A₂.

One of the clamp-on ammeters 5, 7 is then placed around one of the supply cables 9, 9′ of the first field A₁F₁, and the other clamp-on ammeters 9, 9′ around one of the supply cables of the second field A₁F₂. If both simultaneously measured currents have the same magnitude, then the associated fields A₁F₁ and A₁F₂ must also have identical size, i.e., under normal conditions, current is generated undisturbed. A situation where both fields A₁F₁ and A₁F₂ have the same fault is very unlikely and is therefore not taken into consideration at this time. The ratio between the measured currents is then formed, with the ratio having the value VF₁₋₂ (ratio field between field 1 and field 2). For identical currents, the ratio VF₁₋₂ is equal to 1:1=1. Thereafter, one of the clamp-on ammeters 5, 7 is placed around one of the supply cables 9, 9′ of the second field A₁F₂, whereas the other clamp-on ammeters 7 is placed around one of the supply cables 9, 9′ of the third field A₁F₃. It would be sufficient in theory if only the clamp-on ammeter 5, 7 which was previously applied on the first field A₁F₁ is moved to the field A₁F₃. However, this would have to be taken into account later when forming the ratio, which would then have to be inverted so that the desired ratio VF₂₋₃ between the currents A₁F₂ and A₁F₃ is obtained, and not the ratio between the currents A₁F₃ and A₁F₂.

One then proceeds successively pair-for-pair through preferably all fields F of the facility part A₁ having the reduced power, unless at the last field F₈ the currents of the fields 7 and 8 are compared with each other and the ratio VF₇₋₈ is formed. If only the third strand S₃ is defective, as assumed in this case, then the result is a sequence of ratios VF₁₋₂=1, VF₂₋₃=1, VF₃₋₄=1, VF₄₋₅=1.11, VF₅₋₆=0.9, VF₆₋₇=1 and VF₇₋₈=1. In principle, the process could be terminated after forming the ratio VF₅₋₆, because a fault has already been detected. If the measurement performed at the beginning in the comparison of the facility indicates more than one fault, then all fields should be examined.

After the defective field F₅ has been identified, the clamp-on ammeters 5, 7 are placed in a similar manner around one of the supply cables 9 or 9′ of two preferably adjacent strands. Starting with the first and second strand S₁ and S₂, a ratio VS₁₋₂ (strand ratio between strand 1 and strand 2)=1 is obtained, because those strands S₁ and S₂ are intact. The faulty strand S₃ is included in the measurement process during the next measurement between the subsequent strand pair S₂ to S₃, resulting in a ratio VS₂₋₃=1:0=infinity, because the current flow in the third strand S₃ is interrupted. The following ratio VS₃₋₄ would then be 0:1=0, whereafter the strand ratios VS would again be=1.

Due to the high strand voltage, the damaged module S₃M₃ in the third strand S₃ is preferably measured at night, when the PV facility is switched off. This can be done, for example, by disconnecting the plug connection between the fifth module S₃M₅ and the sixth module S₃M₆, so that half of the third strand S₃ can be tested for a break. After determining that the break must be located in the first five modules S₃M₁ to S₃M₅, the plug connection between the modules S₃M₃ and S₃M₄ can be disconnected. The subsequent current continuity measurement would detect the fault in the first part of the modules S₁M₁ to S₃M₃, which would then have to be tested individually for a discontinuity in the current-conducting path.

The individual power output of each field F₁ to F₈ can be tested via a single current measurement by using the existing ratios VF₁₋₂ to VF₇₋₈. The current can be measured stationarily with a current measuring device fixedly installed on one of the fields F, or with a mobile device, as is done in the present arrangement. To this end, all PV units must be connected to the same inverter which is held at a constant voltage during all DC measurements, by particularly setting the MPP (Maximal Power Point) controller of the inverter WR to a constant voltage. With several PV facilities, like with the facilities A₁ and A₂ illustrated in FIG. 1, the voltage must be maintained at a constant value during all DC measurements by setting the MPP (Maximal Power Point) controller of all inverters, here WR₁ and WR₂, to the constant voltage.

For example, if the current value of the first field F₁ is measured, then one knows based on the previously determined, now known ratio VF₁₋₂ how the current value of the second field F₂ looks, because the fields are connected to the same inverter WR₁ (or to the adjusted voltage for several inverters) and therefore have the same voltage. The current on one of the PV units is then determined at a later time, after the original acquisition of the measured value, and the total current is determined in an additional evaluation unit from the present current value and the ratios of the stored measured value, or the total power of the photovoltaic facility is determined by including the corresponding values for the operating voltage.

Unlike with the aforedescribed ideal situation assumed only for illustrative purposes, a PV facility PA₁ has been assumed where the characteristic of each field F is different from that of the other fields. This variance is due to the manufacturing tolerance of the PV modules M, with installation inexactness in the plug connections, the inclination angle with respect to the horizontal, the curvature of the terrain ground, etc. It is therefore advantageous to await a so-called measurement day following they installation of the facility A₁, when the generated current of each of the fields F of the facility A₁ is measured under the same conditions of temperature, voltage, solar intensity, etc. The determined values for the ratios VF are then stored as reference ratios in a memory element. The theoretical total power of the facility A₁ can then be later projected from the stored reference ratios and the actual measured current.

Advantageously, one of the PV units, in particular the fields F, can be identified as a reference PV unit according to standardized test conditions (STC) defined for photovoltaic modules for determining the standard power by measuring the current, the voltage, irradiation intensity and direct or indirect temperature measurements on the semiconductor, in order to thereafter compute the standard power (STC) of another PV unit linked by way of the current value pairs. Alternatively, the STC method may be omitted and the PV unit (e.g., field F) which attained the highest power on the measurement day can be defined as reference standard. All other PV fields F are then referenced to this optimal field, i.e., ratioed according to the lower current values. In a subsequent measurement, all the other fields F would have to become smaller compared to this reference field assuming uniform aging and degradation of the modules M. If this is not the case or if the total power is inexplicably low, e.g., has decreased below a value of 95% of the standard power, then all fields F must be measured again with the aforementioned method. If a significantly different ratio is noticed among the ratios VF₁₋₂ to VF₇₋₈, then the respective fields F must be further analyzed with the approach used for finding a fault in a strand S. In summary, a defect can be readily identified by simultaneously measuring the current through a corresponding one of the supply cables 9, 9′; 11, 11′; or 13, 13′ of the two PV units S, F or A forming a pair, and by forming the ratio VF of the two currents and by comparing the ratio VF with a comparison ratio formed from measured values of the DC currents that were flowing through the corresponding one of the supply cables 9, 9′; 11, 11′; or 13, 13′ of the two PV units S, F or A at a time prior to the time of the measurement.

The connecting or supply cables 9, 9′; 11, 11′; 13, 13′ may be routed close to each other or may also be separated by a longer distance. Typically, no dedicated bus is formed for the fields F, and the supply cables 9, 9′; 11, 11′; 13, 13′ are instead routed individually to the inverter WR, where they converge in a control cabinet. The connecting cables associated with the strands S can be easily identified by visual inspection. In particular for a repeat measurement at the later time, it is necessary to know around which of the connecting cables 9, 9′; 11, 11′; 13, 13′ the clamp-on ammeters 5, 7 must be placed. It is therefore advantageous to store information identifying the location of the measurement together with the pair of the current measurement or with the ratio. This can be accomplished for test locations separated by several meters by using GPS as position registration means, which simultaneously with the likewise simultaneous measurement of the current value pair records and stores the coordinates of the measurement. For more distant test locations, an RFID chip may also be used for this task, which is attached to a support of the respective fields F and which releases the repeated measurement only when the test device is at a location defined by the RFID chip. The separation between the test locations must be large enough so that the chips operating in a transponder mode can be unambiguously distinguished. For a measurement and/or repeat measurement in a small space, a barcode is advantageous which may be located on a label attached to one of the connecting cables 9, 9′; 11, 11′; 13, 13′. The label can be directly glued onto the connecting cable. At the time the current is measured, the barcode is then registered simultaneously by using a suitable reading device, which registers the barcode and stores the same with the current value pair or with the ratio. The measured values for each pair can also be transmitted together with the identification and optionally the current operating voltage wirelessly to a data processing site, where the ratio is then formed, the power is determined, defects are identified, etc.

For averaging artifacts during the simultaneous measurement, the current values provided by the test data acquisition unit are not directly processed; instead, a plurality of measurements is performed within short intervals, i.e., within several seconds or fractions of a second. Subsequently, the arithmetic mean is formed which can then be used for further processing, for example for computing the ratio.

The apparatus for performing the method will now be described with reference to FIG. 2. Shown are exemplary fields A₁F₂ and A₁F₃ with the connecting cables 9 and 9′ extending perpendicular to the drawing plane. One of the clamp-on ammeters 5 is placed around the connecting cable 9′ of the field A₁F₂, whereas the other clamp-on ammeter 7 is placed around the connecting cable 9 of the field A₁F₃. The clamp-on ammeters 5, 7 are standard clamp-on ammeters provided with a handle to facilitate simple and rapid change.

The apparatus includes a selection switch 15 which defines the measurement range required for the current measurement. The range for the current is, for example, 1000 amperes in the position A for the facility, for example 100 amperes for the current in the position F for a field, and about 10 amperes in the position S for a strand S. Two cables 17a, 17b extend from the clamp-on ammeters 5, 7 to the test data acquisition unit 3. A receiver 19 which captures the location data from position registration means transmits the identification of the test location or of the measurement site MS to the test data acquisition unit 3. Preferably, a barcode is used as position registration means when the distance of the cables 9, 9′ from the fields A₁F₁ to A₁F₈ is small, wherein the receiver 19 is then a barcode reader. The barcode 21 can be affixed directly to the cables 9, 9′. For larger distances between the test locations MS, an RFID tag 21a is advantageous, which is attached proximate to the test location MS, for example in the present example between the fields A₁F₂ and A₁F₃ on the support structure (not shown) of the PV modules M. The RFID tag 21a has a receiving or reaction range of about 2 m and registers by way of a transponder function when the test data acquisition unit 3 is in its proximity. If the measurement is performed while the unit 3 is located within the communication range of the RFID label 21a, then the measured current values of the current value pair I₂ and I₃ are transmitted together with the identification of the test location MS₂₋₃ to an evaluation unit 23 or wirelessly via antennae 25 to an external data processing site 27. Depending on the structure and size of the fields F, the GPS position and the measured values I₂ and I3 may be determined together and the coordinates of the position combined directly with the current value pair I₂ and I₃ into a single data set.

The evaluation unit 23 includes a ratio former 29 which forms from the measured current values I₂ and I₃ the ratio, meaning I₂/I₃, which is supplied as output signal s₁ to the first input of a comparator or a comparison unit 31. A reference ratio V_{ref}, which was derived from a freely selectable, measurement earlier than the day of the actual measurement, in particular on the day of the startup, is applied at the second input of the comparator 31. If the actual ratio I₂/I₃ is different by a predetermined value, for example by 5%, then an irregularity in the performance of one of the fields A₁F₂ or A₁F₃ can already be inferred. If the ratio I₂/I₃ is greater than one, then the field A₁F₃ must have smaller current than expected. Conversely, for a ratio I₂/I₃ smaller than one, the field A₁F₂ must have smaller current than expected. Instead of a comparison with the reference ratio V_{ref}, a comparison can also be made with the last registered ratio V for this current pair. The comparator 31 has for this purpose an additional input, to which a signal s₂ is applied which is read from a memory element 33 for the ratios V. This comparison allows an assessment of the degradation or the occurrence of a fault compared to the last measurement and not with the reference value V_{ref} that was formed, for example, at startup and is stored in a dedicated memory 35 for the reference values V_{ref}. The signal s₁ from the ratio former 29 is also supplied to the memory element 33 for the ratios V.

The memory element 33 for the ratios V is also connected via a signal line s₃ with a linking unit 37 which combines these position data also with the associated ratios V in much the same manner as the measured current values I₂, I₃ were previously combined with the position data of the test location in the test data evaluation unit 3. The ratios V together with the identification of the test site MS are supplied to the output of the linking unit 37 via a signal line s₄. The combined data pairs of the ratio V, on one hand, and the test site MS, on the other hand, are stored in a dedicated data memory element 38.

The signal line s₄ extends to a multiplication unit 39 which multiplies the ratios for predetermined test sites MS. If the expected total current I_{ges} is of interest for the eight fields F₁ to F₈, then the current I₁ is measured on the first field 1, and the expected current I of all subsequent seven fields F₂ to F₈ is computed by adding the current values I₁+(I₁*V₁₋₂)+(I₁*V₂₋₃)+(I₁*V₃₋₄)+ . . . (I₁*V₇₋₈)=I_{ges}. It should be mentioned here that it a required current value can advantageously be measured at a stationary current measurement site 41, which measures the measured current permanently or upon request, optionally with the associated field voltage. The stationary current measurement site 41 can advantageously be constructed next to the field F, which has the best power performance of all fields after construction of the facility. For example, the stationarily measured current can be used as reference current I_{ref} for accessing the generated power of all other fields F. An additional memory element 43 is connected to the multiplication unit 39, in which the results of the multiplication are stored for further use, for example for computing the theoretical power of any of the fields F.

While in the past several fields F with reduced power output were detected, it is now of interest to which extent the sum of the fields with reduced power can affect the total power, for example can the current 1₃ from the field A₁F₃ with the defective module S₃M₃ be determined by multiplying the current I₁ from the first field F₁ with the two ratios V₁₋₂ and V₂₋₃ and, if several inverters WR are employed, and can the power be determined through multiplication with the voltage of the connected inverter WR. Due to the defective module M, the ratio VF₂₋₃ is greater than under normal conditions and hence reflects the already known smaller current I₃. In this way, all fields F previously identified can be investigated and the sum of the smaller power output of all defective fields F can be computed using only a single current measurement for each facility A. In the event that a strand S or a field F has a measured current value of zero, the ratio V to the preceding and subsequent strand S or field F would be defined as infinite or zero. In this case, any ratio of zero or infinite is omitted when linking the measured value for determining the power, and a ratio V is formed from the preceding and subsequent strand S or field F.

In addition or alternatively, instead of supplying the measured currents I₂ and I₃ to the ratio former 29, the current values I₂ and I₃ can also be directly supplied to a comparator 45 which compares the currents I₂, I₃ directly with reference currents measured at an earlier time and stored. Likewise, the current pair value I₂, I₃ can be supplied to the input of a power comparator 47 which has an additional input for the value of the voltage U₁ at the inverter WR₁, or if several inverters WR are employed, a commensurate number of inputs for the operating voltage value U of the respective inverters WR. Lastly, an input is provided on the power comparator 47 at which a signal s₅ is applied as a comparison reference signal. The signal s₅ reflects the reference power P_{ref} either of the reference PV unit, i.e. in the present example the reference field F₄, or the power from previous measurements. The power comparator 47 has an output 49 supplying an alarm signal in the event of an impermissibly high deviation from the comparison reference value or among the power values.

FIG. 2 shows in addition a computing unit 49 which is connected to the evaluation unit 3 and receives from the evaluation unit 3 the multiplied current values I₁, (I₁*V₁₋₂), (I₁*V₂₋₃), (I₁*V₃₋₄), . . . (I₁*V₇₋₈) (* indicates multiplication). The currents from all fields F are summed in the computing unit 49 and supplied as value of the total current I_{ges} of the facility A₁ to an additional multiplication unit 51, to which also the voltage value U of the reference field, in the present example the field F₄, is supplied. The output signal s₆ of the additional multiplication unit 51 is the theoretical power P_{theoretisch} which is displayed on a display 53. In addition, the actual instantaneous power Pᵣₑₐₗ determined from the actual current measured at the inverter WR can be displayed on the display 53, enabling a continuous visual comparison of the actual power P with the theoretically expected power.

FIG. 3 shows the housing of the apparatus 1, which has inside an integrated DC source 55, which supplies a line 59 with a calibration current I_{calibration} via a measurement shunt resistor 57. The line 59 extends partially through the interior of a hoop 61 formed on the housing. The hoop 61 and the line 59 are dimensioned so that they can be simultaneously surrounded by the two clamp-on ammeters 5, 7. The calibration current loop is closed via a switch 63. This switch 63 is preferably implemented as pushbutton switch or lever on the housing face. In principle, the clamp-on ammeters 5, 7 may surround a single connecting cable 9, 9′ of one of the PV units A, S, F for calibrating the two clamp-on ammeters 5, 7 relative to one another. However, the aforedescribed calibration via the measurement shunt 57 is preferred for a more precise determination of the absolute measured value and is hence preferred over the relative calibration.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A measurement method for simultaneous measurement of currents of at least two photovoltaic (PV) units, comprising the steps of:
measuring a first current value of a first of the at least two PV units with a first clamp-on ammeter and measuring a second current value of a second of the at least two PV units with a second clamp-on ammeter,
transmitting the first current value and the second current value to a test data acquisition unit, and
determining in an evaluation unit a performance of the first PV unit and the second PV unit from the first current value and the second current value transmitted to the test data acquisition unit.

2. The measurement method of claim 1, wherein with identically constructed PV units operating at an identical operating voltage, the PV unit having a smaller current is identified as the PV unit having less power output.

3. The measurement method of claim 1, wherein with identically constructed PV units operating at the different operating voltages, the PV unit having a smaller product of measured current and measured operating voltage of the PV unit associated with the respective current value is identified as the PV unit having less power output.

4. The measurement method of claim 1, wherein with differently constructed PV units operating at an identical operating voltage, the PV unit having a smaller current is identified as the PV unit having less power output.

5. The measurement method of claim 1, wherein with differently constructed PV units operating at different operating voltages, the PV unit having a smaller product of measured current and measured operating voltage of the PV unit associated with the respective current value is identified as the PV unit having less power output.

6. The measurement method of claim 2, wherein the first and second PV units are set to an identical operating voltage during the simultaneous measurement or are connected to a single inverter.

7. The measurement method of claim 4, wherein the first and second PV units are set to an identical operating voltage during the simultaneous measurement or are connected to a single inverter.

8. The measurement method of claim 1, comprising the steps of:
measuring the first current on a first connecting cable of the first PV unit, simultaneously measuring the second current on a second connecting cable of the second PV unit,
forming a ratio of the first measured current to the second measured current, and
comparing the ratio with a comparison ratio formed from measured values of first and second currents that were flowing through the respective connecting cables of the first and second PV unit at an earlier time.

9. The measurement method of claim 1, wherein the PV system comprises at least three PV units, the method comprising with the steps of:
i. grouping the at least three PV units in pairs and measuring simultaneously a corresponding current value on each of the pairs, until the current value of each of the at least three PV units has been measured at least once;
ii. computing a ratio of the corresponding current values measured for each pair; and
iii. storing the computed ratios in an electronic memory element.

10. The measurement method of claim 9, wherein the pairs in step i) are formed by grouping adjacent PV units, wherein the pairs of adjacent PV units are selected so that at least partially a contiguous chain of pairs is formed, with each pair representing a link of the chain.

11. The measurement method of claim 9, comprising the steps of:
in a step iv) carried out subsequent to step i), measuring an actual current value on one of the at least three PV units, and
in a step v), determining with a computing unit a total current of the photovoltaic system or, determining with the computing unit a theoretical total power of the photovoltaic system by taking into consideration corresponding operating voltage values of the at least three PV units or the actual current value and the computed ratios stored in the step iii).

12. The measurement method of claim 9, further comprising the steps of:
registering an identification of a test location or a location of the current measurement at each measurement following step i), and
storing the identification of the test location or the location of the current measurement together with current values of the pair measured at the test location or the location of the current measurement or a ratio computed from the current values of the pair.

13. The measurement method of claim 10, wherein each of the adjacent PV units of a pair comprises a first and a second connecting cable, and wherein the current value is measured on the first connecting cable of one of the adjacent PV units of the pair and on the second connecting cable of the other of the adjacent PV units of the pair.

14. The measurement method of claim 1, wherein PV unit comprises a strand of several PV modules connected in series.

15. The measurement method of claim 1, wherein a PV unit comprises a field formed from several strands which are connected in parallel.

16. The measurement method of claim 12, further comprising the step of sending the measured current values of each pair together with the identification wirelessly to a data processing site.

17. The measurement method of claim 12, wherein the location of the measurement is recorded with a suitable position registration means using GPS, an RFID chip or a barcode concurrently with the current measurement.

18. The measurement method of claim 8, wherein a plurality of first and second current values are measured consecutively within a short time, wherein the test data acquisition unit outputs an arithmetic mean of the plurality of first and second current values, and wherein the ratio if formed using the arithmetic mean of the first and second current values.

19. The measurement method of claim 6, wherein the operating voltage measured between connecting cables connecting the at least two photovoltaic units to a single inverter is stored together with the measured current value.

20. The measurement method of claim 1, wherein all PV units are connected to a single inverter which is maintained during all current measurements at a constant operating voltage value by setting a MPP (Maximal Power Point) controller of the inverter to the constant operating voltage value.

21. The measurement method of claim 1, wherein some of the PV units are connected to different inverters which are maintained during all current measurements at an identical constant operating voltage value by setting a MPP (Maximal Power Point) controller of all inverters to the identical constant operating voltage value.

22. The measurement method of claim 1, further comprising the steps of placing the first clamp-on ammeter and the second clamp-on ammeter simultaneously around a single connecting cable of one of the at least two PV units and calibrating the two clamp-on ammeters relative to each other.

23. The measurement method of claim 10, further comprising identifying one of the at least three PV units as a reference-PV unit according to standardized test conditions (STC) defined for photovoltaic modules for determining a standard power by way of a current measurement, a voltage measurement, an incident radiation intensity and a direct or indirect temperature measurement on the semiconductor, and computing the standard power (STC) of a PV unit that is part of a link of the chain.

24. A system for simultaneous measurement of current values of at least two photovoltaic (PV) units, comprising:
two clamp-on ammeters for simultaneous measurement of the current values of the at least two PV units,
a test data acquisition unit connected to the two clamp-on, and
an evaluation unit which evaluates the current values received from the test data acquisition unit with respect to absolute value and a computed mutual ratio to each other, or which evaluates a power output by including a voltage between connecting lines of the at least two PV units.

25. The system of claim 24, wherein the system is a mobile system.

26. The mobile system of claim 25, further comprising a position registration means for measuring a position of the two clamp-on ammeters surrounding the connecting lines at a time of the measurement, and
at least one of an antenna for transmitting the measured current values and position data and a data memory element for recording the measured current values and the position data.

27. The mobile system of claim 25, further comprising a calibration system for calibrating the two clamp-on ammeters, the calibration system comprising an integrated DC current source, which supplies a calibration current to a line constructed for simultaneously receiving both clamp-on ammeters, wherein the calibration current is supplied via a measurement shunt resistor.

28. The mobile system of claim 26, wherein the position registration means comprise GPS data, a barcode readable with a barcode reader, or an RFID chip readable with a communicating receiver, and wherein data in the position registration means are queried at the time of the measurement.

29. The system of claim 24, comprising:
a stationary current and voltage measurement unit which stationarily measures the current value of a single of the at least two PV units, and
a computing device receiving from the stationary current and voltage measurement unit the measured current result, said computing device computing a theoretical total power of the PV system from ratios of current value pairs and from the stationarily measured current value as well as from a voltage value determined for the current value pairs and a stationarily determined voltage value.
